(19) United States
(12) Patent Application Publication
(10) Pub. No.: US 2016/0365680 A1
(43) Pub. Date: Dec. 15, 2016

(54) METHOD AND APPARATUS FOR INITIATING A CHANGE IN STATE OF AN ELECTRONIC DEVICE THROUGH A CONNECTOR RECEPTACLE

(71) Applicant: Motorola Mobility LLC, Chicago, IL (US)

(72) Inventors: Vidyadhar Gurram, Gurnee, IL (US); Roshan Kamath, Evanston, IL (US)

(21) Appl. No.: 15/084,547

(22) Filed: Mar. 30, 2016

Related U.S. Application Data
(60) Provisional application No. 62/173,152, filed on Jun. 9, 2015.

(51) Int. Cl. H01R 13/70; H03K 17/96; H02N 2/18

(52) U.S. Cl. CPC H01R 13/70; H02N 2/18; H03K 17/964

(57) ABSTRACT

An apparatus, such as can be included in an electronic device, performs a method for initiating a change in state of the electronic device through a connector receptacle. The apparatus includes a connector receptacle physically arranged to receive a mated connector of an external device to the electronic device. The apparatus also includes state-change activation circuitry coupled to the connector receptacle. The state-change activation circuitry is physically arranged to initiate the change in state of the electronic device in response to an external force applied to the connector receptacle.

### RELATED APPLICATIONS

The present application is related to and claims benefit under 35 U.S.C. §119(e) from U.S. Provisional Patent Application Ser. No. 62/173,152, filed Jun. 9, 2015, titled “Method and Apparatus for Initiating a Change in State of an Electronic Device Through a Connector Receptacle” (attorney docket no. MM01186), which is commonly owned with this application by Motorola Mobility LLC, the entire contents of which are incorporated herein by reference.

### FIELD OF THE DISCLOSURE

The present disclosure relates generally to electronic devices and more specifically to initiating a change in state of an electronic device through a connector receptacle.

### BACKGROUND

One design feature for electronic devices is the form factor. The form factor relates to the size, shape, and style of the electronic devices. The form factor is becoming increasingly important to address users' desires for aesthetic appeal and enhanced interactivity with electronic devices. In this regard, designers have attempted to provide modern electronic devices with sleeker, e.g., thinner and lighter, form factors and with a capability, for some functions, of user interaction without using touch, e.g., a “no hands” feature. However, some newer features, such as the no-hands feature, oftentimes have undesired effects, such as increased power consumption. Therefore, an improved form factor continues to be a high priority in designing electronic devices.

### BRIEF DESCRIPTION OF THE FIGURES

The accompanying figures, where like reference numerals refer to identical or functionally similar elements throughout the separate views, form part of the specification and illustrate embodiments in accordance with the included claims.

FIG. 1 shows a pictorial diagram that includes an electronic device having apparatus configured to initiate a change in state of the electronic device using a connector receptacle, in accordance with some embodiments.

FIG. 2 shows a block diagram illustrating components of an electronic device that includes apparatus configured to initiate a change in state of the electronic device using a connector receptacle, in accordance with some embodiments.

FIG. 3 shows a pictorial diagram illustrating an embodiment of apparatus configured to initiate a change in state of an electronic device using a connector receptacle.

FIG. 4 shows a flow diagram illustrating a method for initiating a change in state of an electronic device using a connector receptacle, in accordance with some embodiments.

FIG. 5 shows a pictorial diagram illustrating the embodiment of apparatus shown in FIG. 3 when an external force is applied to the apparatus.

FIG. 6 shows a pictorial diagram illustrating the embodiment of apparatus shown in FIG. 3 when an alternative external force is applied to the apparatus.

FIG. 7 shows a flow diagram illustrating an embodiment of a method for initiating a change in state of an electronic device using a connector receptacle when the electronic device is in an off state.

FIG. 8 shows a flow diagram illustrating embodiment of a method for initiating a change in state of an electronic device using a connector receptacle when the electronic device is in an on state.

FIG. 9 shows a pictorial diagram illustrating another embodiment of apparatus configured to initiate a change in state of an electronic device using a connector receptacle.

FIG. 10 shows a pictorial diagram illustrating the embodiment of apparatus shown in FIG. 9 when an external force is applied to the apparatus.

FIG. 11 shows a pictorial diagram illustrating another embodiment of apparatus configured to initiate a change in state of an electronic device using a connector receptacle.

FIG. 12 shows a pictorial diagram illustrating the embodiment of apparatus shown in FIG. 11 when an external force is applied to the apparatus.

FIG. 13 shows a pictorial diagram illustrating another embodiment of apparatus configured to initiate a change in state of an electronic device using a connector receptacle.

FIG. 14 shows a pictorial diagram illustrating the embodiment of apparatus shown in FIG. 13 when an external force is applied to the apparatus.

FIG. 15 shows a pictorial diagram illustrating another embodiment of apparatus configured to initiate a change in state of an electronic device using a connector receptacle.

FIG. 16 shows a pictorial diagram illustrating the embodiment of apparatus shown in FIG. 15 when an external force is applied to the apparatus.

FIG. 17 shows a pictorial diagram illustrating another embodiment of apparatus configured to initiate a change in state of an electronic device using a connector receptacle.

FIG. 18 shows a pictorial diagram illustrating the embodiment of apparatus shown in FIG. 17 when an external force is applied to the apparatus.

FIG. 19 shows a pictorial diagram illustrating the embodiment of apparatus shown in FIG. 17 when the applied external force is released.

FIG. 20 shows a timing diagram related to the embodiment of apparatus shown in FIGS. 17, 18, and 19.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present teachings. In addition, the description and drawings do not necessarily require the order presented. It will be further appreciated that certain actions and/or steps may be described or depicted in a particular order of occurrence while those skilled in the art will understand that such specificity with respect to sequence is not actually required.

The apparatus and method components have been represented, where appropriate, by conventional symbols in the drawings, showing only those specific details that are pertinent to understanding the embodiments of the present teachings so as not to obscure the disclosure with details that will be readily apparent to those of ordinary skill in the art having the benefit of the description herein.

### DETAILED DESCRIPTION

Generally speaking, pursuant to various embodiments described herein, the present disclosure provides apparatus, an electronic device, and a method to initiate a change in state of the electronic device through a connector receptacle. An example apparatus includes a connector receptacle coupled to state-change activation circuitry. The connector receptacle is configured to receive a mated connector of an external device to an electronic device. The state-change activation circuitry is configured to initiate a change in state of the electronic device in response to an external force applied to the connector receptacle.

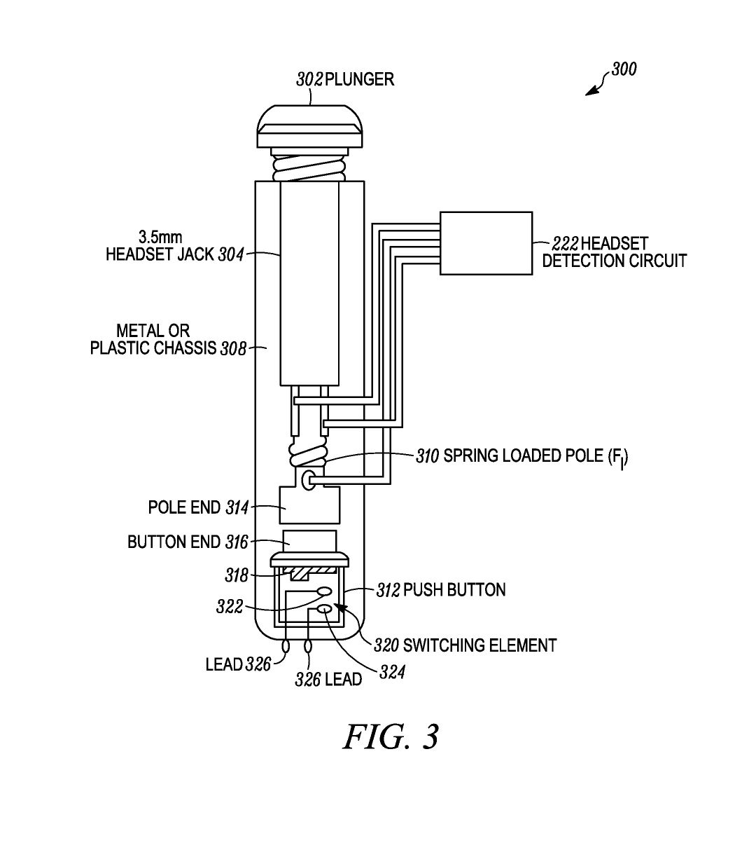

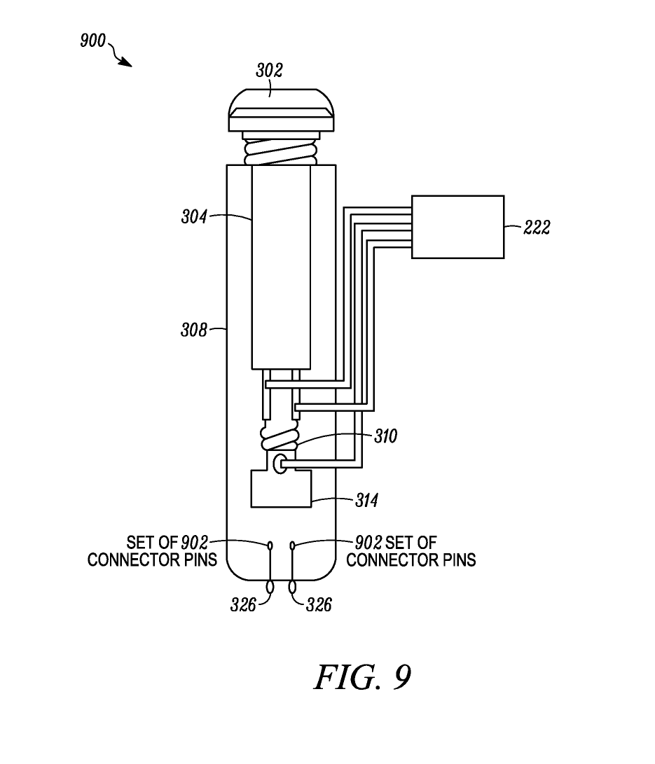

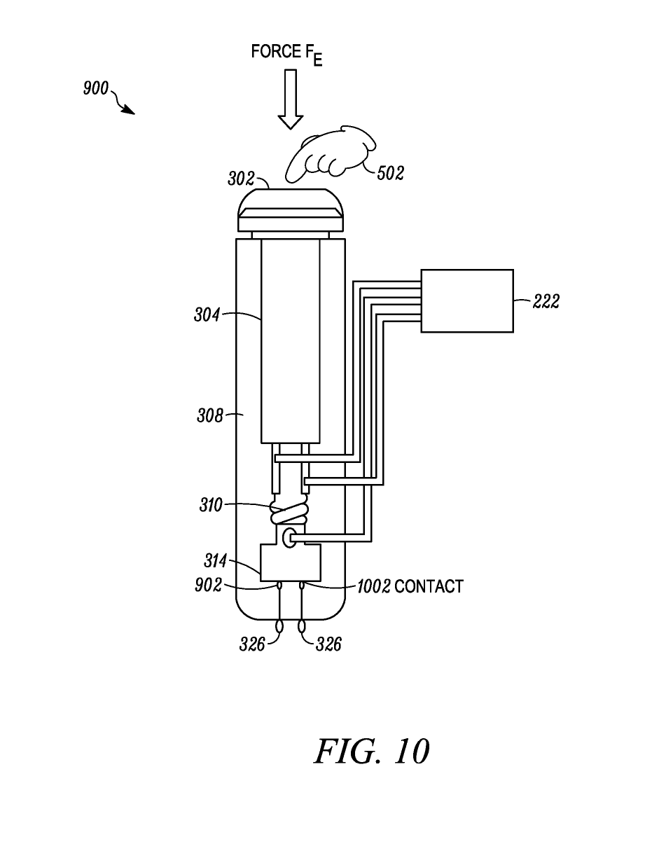

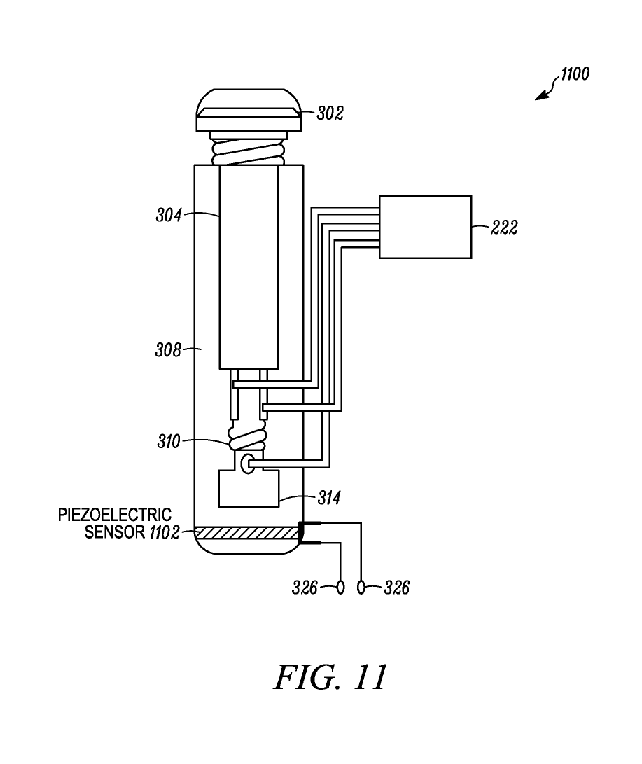

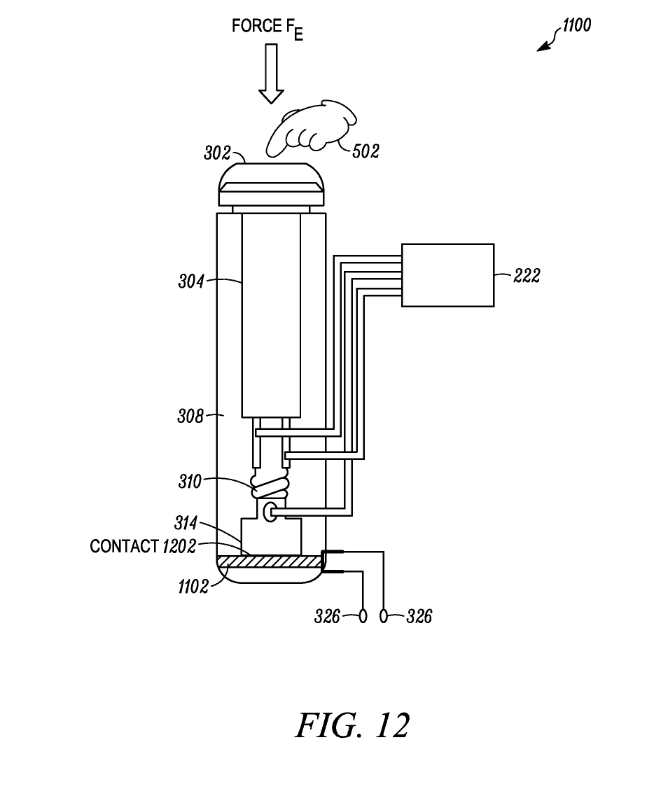

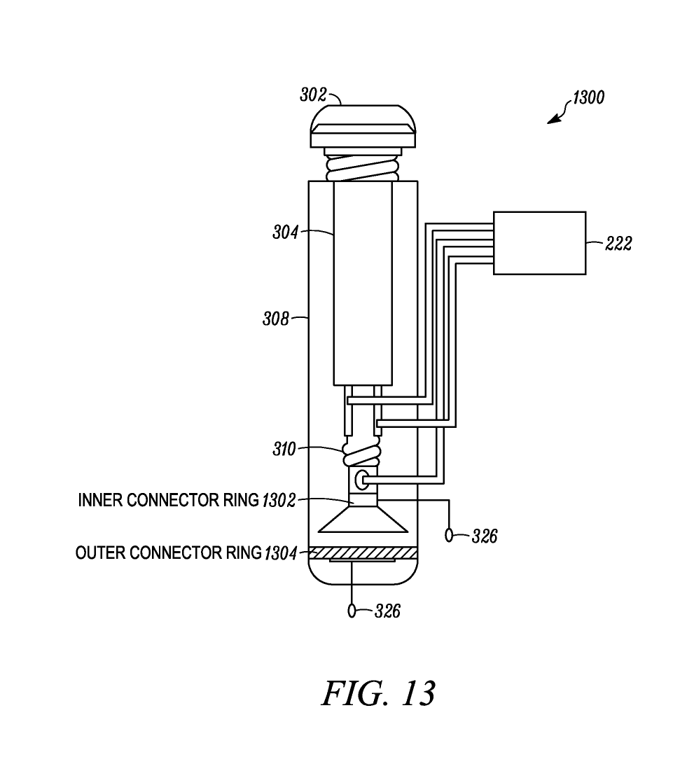

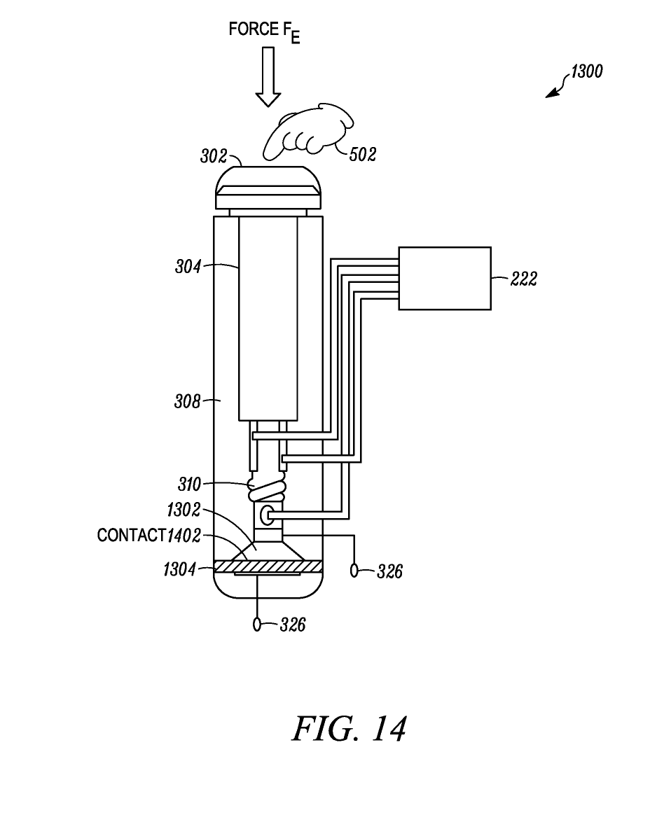

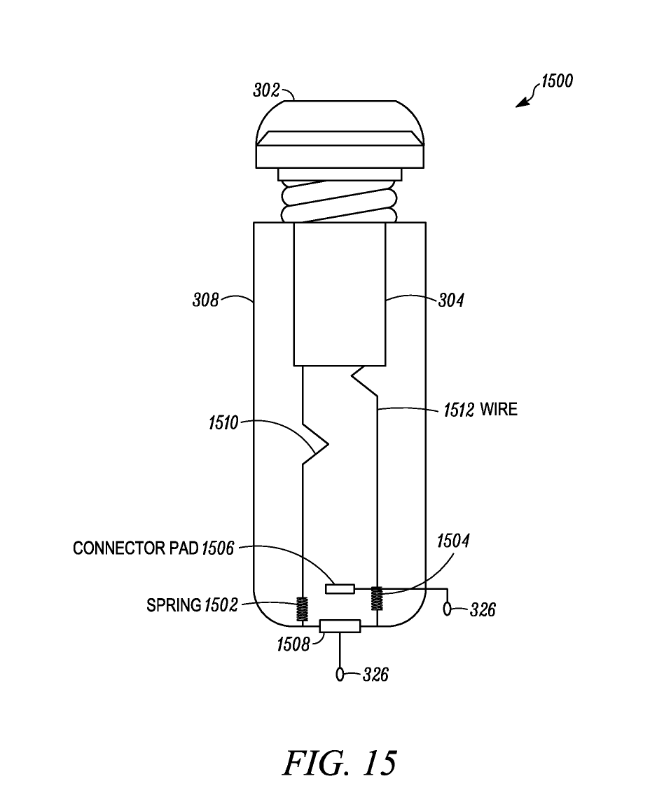

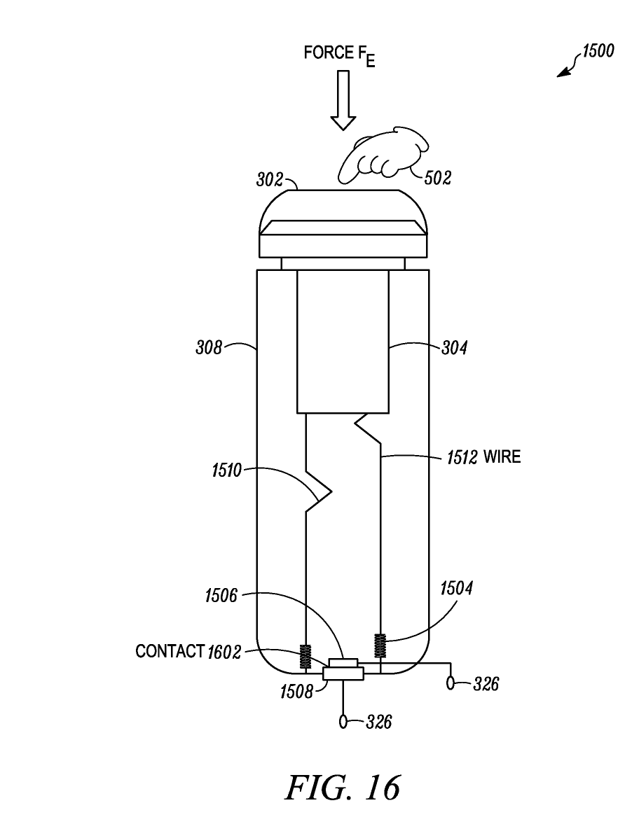

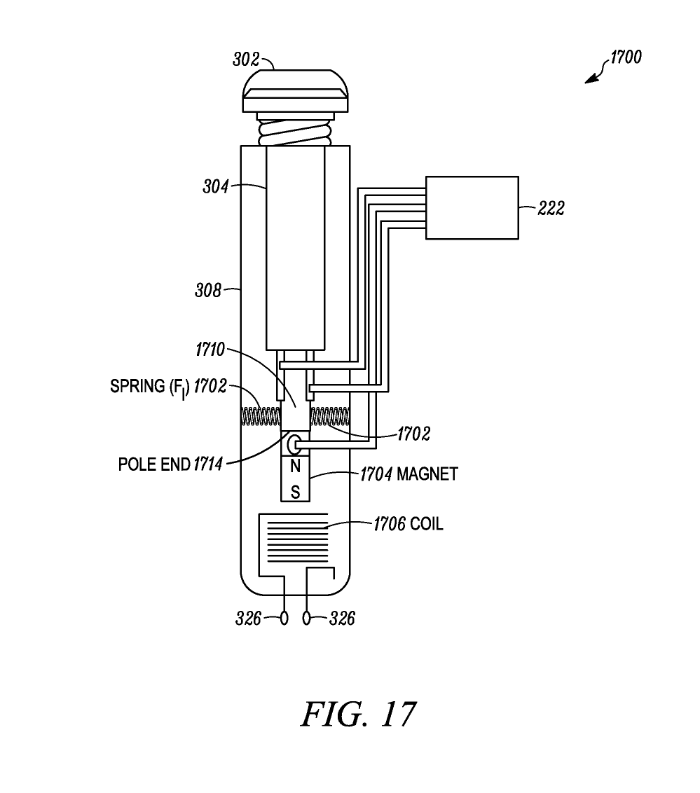

An example electronic device includes a connector receptacle coupled to state-change activation circuitry. The connector receptacle is configured to receive a mated connector of an external device to the electronic device. The state-change activation circuitry includes first and second hardware elements (also referred to herein simply as elements) configured to cooperatively operate in response to an external force applied to the connector receptacle to, thereby, initiate a change in state of the electronic device. For instance, the first and second hardware elements include at least two of: a spring-loaded pole, such as shown in FIGS. 3, 5, 6, 9, 10, 11, 12, 13, 14, 17, 18, and 19; a component containing a switching element, such as shown in FIGS. 3, 5, and 6; a connector pin, such as shown in FIGS. 9 and 10; a connector ring, such as shown in FIGS. 13 and 14; a connector pad, such as shown in FIGS. 15 and 16; a spring, such as shown in FIGS.15 and 16; a wire, such as shown in FIGS. 15 and 16; a magnet, such as shown in FIGS. 17, 18, and 19; a coil, such as shown in FIGS. 17, 18, and 19; or a piezoelectric sensor, such as shown in FIGS. 11 and 12.

An example method includes receiving an external force onto a connector receptacle of an electronic device, wherein the connector receptacle is configured to receive a mated connector of an external device to the electronic device. The method further includes initiating a change in state of the electronic device in response to the external force.

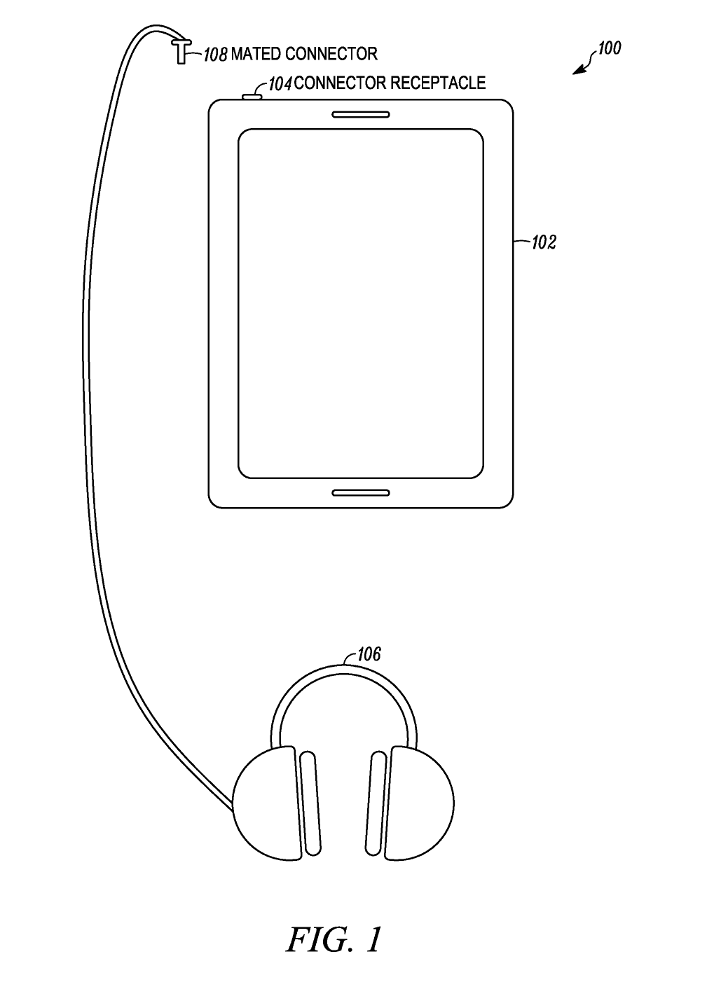

FIG. 1 shows a pictorial diagram 100, which includes an electronic device 102 having apparatus configured to initiate a change in state of the electronic device 102 using a connector receptacle 104 of the electronic device 102. The electronic device 102 is illustrated as a mobile device, such as a smartphone. However, the electronic device 102 can represent another device, such as a tablet computer, a personal digital assistant, a wearable computing device, or a laptop computer, for example.

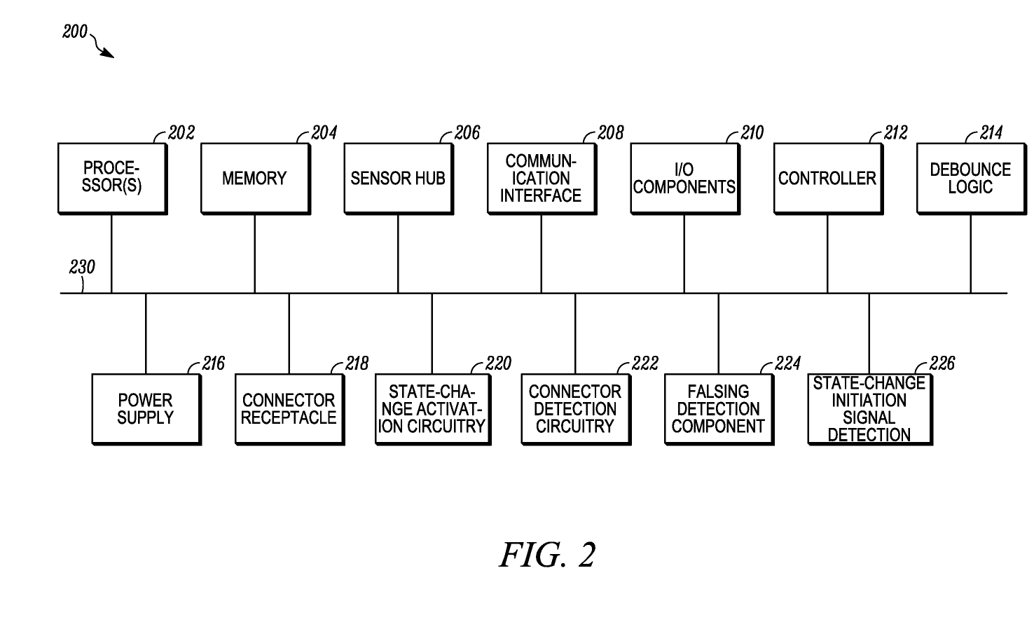

The connector receptacle 104 is configured for receiving a mated connector 108 of an external device 106. As shown, the connector receptacle 104 is configured for receiving the mated connector 108 of an external accessory device 106, namely an external auditory headset 106. Accordingly, embodiments of the teachings herein, including the embodiments described by reference to FIGS. 2 through 20, are directed to initiating a change in state of the electronic device 102 using a connector receptacle configured to receive a mated connector of an accessory device. However, the teachings herein are applicable to other embodiments directed to initiating a change in state of the electronic device 102 using a connector receptacle configured to accept a mated connector of different types of external devices, such as charging devices or auxiliary devices. Example auxiliary devices include, but are not limited to, an external speaker, an external monitor, a printer, etc. Other components are also included in the electronic device 102 but are not explicitly indicated in FIG. 1.

The connector receptacle 104 and the mated connector 108 are considered as mateable, structured, or physically arranged for the connector receptacle 104 to receive the mated connector 108 when the components 104 and 108 have mutually complementary shapes that allow a physical coupling or connection. For instance, as illustrated, the physical coupling or connection is suitable for implementing a communication interface for data flow. In one embodiment, the connector receptacle 104 is a female connector, while the mated connector 108 is a male connector. As stated, for the embodiment shown, the connector receptacle 104 is configured to receive the mated connector 108 of the headset 106. As such, the headset 106 receives audio signals from the electronic device 102 when the connector receptacle 104 and the mated connector 108 are engaged with one another, i.e., mated or coupled together.

FIG. 2 shows a block diagram 200 illustrating components of an electronic device, such as the electronic device 102, that includes apparatus configured to initiate a change in state of the electronic device 102 using a connector receptacle, in accordance with some embodiments. Included within the block diagram 200 are one or more processors 202, a data storage or memory element 204, a sensor hub 206, a communication interface 208, input and output (I/O) components 210, a controller 212, debounce logic circuitry 214, a power supply 216, one or more connector receptacles 218, state-change activation circuitry 220, connector detection circuitry 222, a falsing detection component 224, and a state-change initiation-signal detection circuit 226, which are all operationally and communicatively interconnected by a component 230, such as a system bus and/or other internal connections.

A limited number of device components 202, 204, 206, 208, 210, 212, 214, 216, 218, 220, 222, 224, 226, and 230 are shown at 200 for ease of illustration. Other embodiments include a lesser or greater number of components in an electronic device. Moreover, other components needed for a commercial embodiment of an electronic device that incorporates the components 202, 204, 206, 208, 210, 212, 214, 216, 218, 220, 222, 224, 226, and 230 are omitted from FIG. 2 for clarity in describing the enclosed embodiments.

In general, the state-change initiation circuitry 220 is configured with functionality in accordance with embodiments of the present disclosure as described herein with respect to the remaining figures. “Configured,” “adapted,” “operative,” or “capable,” as used herein, means that indicated components are implemented using one or more hardware elements, which may or may not be programmed with software and/or firmware, as the means for the indicated components to implement their desired functionality. Such functionality is supported by the other hardware shown in FIG. 2, including the device components 202, 204, 206, 208, 210, 212, 214, 216, 218, 222, 224, and 226. For some embodiments, “configured” means that the hardware is physically arranged or has physical characteristics that enable the hardware to perform at least some of its functionality. For example, the connector receptacle and state-change activation circuitry are physically arranged as shown in and described by reference to FIGS. 1, 3, 5, 6, 9, 10, 11, 12, 13, 14, 15, 16, 17, 18, and 19 to initiate a change in state of an electronic device through a connector receptacle.

The processor 202, for instance, includes arithmetic logic and control circuitry necessary to perform the digital processing, in whole or in part, for the electronic device 102 to enable various functions and operations including running one or more applications. For one embodiment, the processor 202 represents a primary microprocessor, also referred to as a central processing unit (CPU), of the electronic device 102. For example, the processor 202 represents an application processor (AP) of the electronic device 102, such as within a tablet, a smartphone, or a laptop computer. In another embodiment, the processor 202 is an ancillary processor, separate from the CPU, wherein the ancillary processor is dedicated to providing the processing capability, in whole or in part, needed for the components of the electronic device 102 to perform at least some of their intended functionality. For a particular embodiment, the teachings herein can facilitate a change in state of the processor 202, e.g., from a sleeping state to a wake state, in response to an external force applied to the connector receptacle 218.

The memory 204 provides storage of electronic data used by the processor 202 and/or other processors or controllers of the electronic device 102 in performing their functionality. Such functionality can include, but is not limited to, running applications, detecting whether the electronic device 102 is within an enclosed space, determining falsing conditions, detecting long- and short-press events, etc. In one embodiment, the memory 204 represents random access memory (RAM). In other embodiments, the memory 204 represents volatile or non-volatile memory. For a particular embodiment, a portion of the memory 204 is removable. For example, the processor 202 uses RAM to cache data while it uses a micro secure digital (microSD) card to store files associated with device states, such as wake, sleep, on, off, and other power-management states.

The sensor hub 206 is configured to sense positioning of the electronic device 102 and to provide an indication of the positioning of the electronic device 102 to the controller 212 and/or the falsing detection component 224 to use, for instance, in determining whether to maintain a current state of the electronic device. Accordingly, the sensor hub 206 includes one or more sensors (not shown) used to determine a position and/or orientation for the electronic device 102. For example, the sensors are used to determine whether the electronic device 102 is inside of an enclosed or confined space, such as a pocket or purse. The associated sensor signals can be electrical, electronic, optical, or magnetic, for instance. Example sensors include, but are not limited to, light emitting diodes (LEDs) and corresponding receivers, imagers, etc. For a further embodiment, the sensor hub 206 includes a processor separate from an application or main processor 202 of the electronic device 102. This decoupling of processing capability enables the processing of sensor data without awaking the main processor 202.

The communication interface 208 facilitates communication between the electronic device 102 and other electronic devices, such as mobile devices or servers. For one embodiment, the communication interface 208 includes a cellular transceiver to enable the electronic device 102 to communicate with other electronic devices using one or more cellular networks. Cellular networks can use any wireless technology that, for example, enables broadband and Internet Protocol (IP) communications including, but not limited to, 3^{rd} Generation (3G) wireless technologies such as CDMA2000 and Universal Mobile Telecommunications System (UMTS) networks, 4^{th} Generation (4G) wireless technologies such as LTE and WiMAX, or 5^{th} Generation wireless technologies.

In another embodiment, the communication interface 208 includes a wireless local area network (WLAN) transceiver that allows the electronic device 102 to access the Internet. The WLAN transceiver allows the electronic device 102 to send and receive radio signals to and from similarly equipped electronic devices using a wireless distribution method, such as a spread-spectrum or orthogonal frequency-division multiplexing (OFDM) method. For some embodiments, the WLAN transceiver uses an IEEE 802.11 standard to communicate with other electronic devices in the 2.4, 3.6, 5, and 60 GHz frequency bands. In a particular embodiment, the WLAN transceiver uses Wi-Fi interoperability standards as specified by the Wi-Fi Alliance to communicate with other Wi-Fi certified devices.

For additional embodiments, the communication interface 208 enables hardwired, rather than wireless, connections to a network infrastructure that allows the electronic device 102 to communicate electronically with other devices. For example, the communication interface 208 includes a socket that accepts an RJ45 modular connector that allows the electronic device 102 to be connected directly to a network router by a category-5 or category-6 Ethernet patch cable. The communication interface 208 can also use a cable modem or a digital subscriber line (DSL) to connect with other electronic devices through the Internet via an Internet service provider (ISP).

The input and output components 210 represent user-interface components of the electronic device 102, which are configured to allow a person to use, program, or otherwise interact with the electronic device 102. For brevity, input components and output components are illustrated as combined I/O components 210. Different electronic devices for different embodiments include different combinations of input and output components 210. In some implementations, the input and output components 210 are separate and distinct, while in other implementations the input and output components 210 have combined functionality. For example, input components can include a keyboard, a trackpad, and a microphone; and output components can include speakers. A touchscreen is an example component that functions both as an output component and an input component.

The controller 212 is configured to at least control power management of the electronic device 102, including, for instance, detecting long- and short-press events and determining whether to maintain or to trigger or cause a change in an operational state, or simply state, of the electronic device 102. Such states include, but are not limited to: power states, e.g., an on state or an off state of the electronic device 102 as a whole; display states, e.g., wake and sleep states of a display of the electronic device 102; and AP or other processor states, e.g., wake and sleep states of a processor of the electronic device 102. Depending on the particular implementation, the controller 212 might include one or more timers, amplifiers, digital and/or analog processing or logic circuitry, or other circuitry or hardware, implemented, for instance, as an integrated circuit, to carry out its intended functionality.

For some embodiments, the controller 212 receives indications, such as a flag, a voltage, a current, or another value or signal, from other hardware components of the electronic device 102 to determine whether to maintain or change the state of the electronic device 102. For a particular embodiment, the controller 212 is coupled to the state-change activation circuitry 220 through the state-change initiation-signal detection circuit 226. Accordingly, the controller 212 is configured to receive an indication from the state-change initiation-signal detection circuit 226. This indication enables the controller 212 to determine, for instance, whether to maintain a current state of the electronic device 102 when an external force is applied to the connector receptacle 104.

Debouncing or debounce logic 214 includes circuitry that controls, e.g., removes, the effect of mechanical vibratory output associated with mechanical switching elements opening and closing or other contact between mechanical elements. Some embodiments of debounce logic 214 can include various combinations flip-flops, counters, and logic gates. Other embodiments of debounce logic 214 can include combinations of circuit elements such as transistors, resistors, capacitors, diodes, and comparators. For the embodiments described herein, debounce logic 214 controls the effect of vibration caused by metal or conductive contacts, pads, pins, or rings, for example, coming into physical contact with each other during completion of closing of an electrical circuit. In short, debounce logic 214 operates to allow the recognition of only a single signal for a single contact between elements, such as elements of the state-change activation circuitry 220. Accordingly, the debounce logic 214 can be included as part of the state-change initiation-signal detection circuit 226 or as separate circuitry that couples the state-change initiation-signal detection circuit 226 to the state-change activation circuitry 220.

The power supply 216 represents a power source that supplies electric power to the device components 202, 204, 206, 208, 210, 212, 214, 218, 220, 222, 224, 226 and/or 230, as needed, during the course of their normal operation. The power is supplied to meet the individual voltage and load requirements of the device components 202, 204, 206, 208, 210, 212, 214, 218, 220, 222, 224, 226, 230 that draw electric current. For some embodiments, the power supply 216 is a wired power supply that provides direct current from alternating current using a full- or half-wave rectifier. For other embodiments, the power supply 216 is a battery that powers up and runs a mobile device. For a particular embodiment, the battery 216 is a rechargeable power source that is configured to be temporarily connected to an external power source to restore a charge of the rechargeable power source when it is depleted or less than fully charged. In another embodiment, the battery 216 is simply replaced when it no longer holds sufficient electrical charge or voltage.

The connector receptacle 218 receives an opposing connector, such as a plug, plunger, probe, or other structured object that fits within the confines of the connector receptacle 218. For a particular embodiment, the opposing connector is considered to be mated or coupled to the connector receptacle 218 when the connector receptacle 218 and the opposing connector are able to transmit data or communication signals or other signaling via their interaction with each other. The connector receptacle 218 can be positioned at multiple locations on the electronic device 102.

The state-change activation circuitry 220 is coupled to the connector receptacle 218. As a result, the state-change activation circuitry 220 facilitates or initiates one or more changes in states of the electronic device 102 in response to an external force applied to the connector receptacle 218. For example, in response to the appropriate amount of force applied to the connector receptacle 218, the state-change activation circuitry 220 provides or initiates the generation of a signal that indicates the reception on the connector receptacle 218 of the appropriate amount of force. This signal can then be analyzed by additional hardware, e.g., the controller 212 and/or the state-change initiation-signal detection circuit 226, to determine whether conditions exist (for instance the requisite amount of external force for the requisite amount of time) to change the state of the electronic device 102. The changes in states of the electronic device 102 include, but are not limited to, changes in power states, display states, or processor states of the electronic device 102.

For some embodiments, the electronic device 102 only implements the present teachings and does not include a separate power key or button to change the operational state of the electronic device 102. Such embodiments can improve the form factor of the electronic device 102 by eliminating at least one button, which can enable a sleeker look and feel for a user and can reduce manufacturing costs. Also, removing the power key provides a path to manufacturing an electronic device with no physical buttons but only software or “soft” buttons for controlling many functions and features of the electronic device such as media, volume, brightness, etc.

For additional embodiments, the state-change activation circuitry 220 includes components or circuitry that translate or convert mechanical energy, e.g., an applied external pressure or external force onto a mechanical component, into an electrical signal or energy to initiate the change in state of the electronic device 102. “Electrical” signal or energy is used herein as a general term to include any signal that can be detected and/or processed such as a voltage, an electrical charge, a current, an electromotive force (EMF), etc. For example, the components of the state-change activation circuitry 220 include a piezoelectric sensor that converts or translates mechanical energy, e.g., pressure or force, into an electrical charge or voltage to initiate the change in state of the electronic device 102, for instance as shown in FIGS. 11 and 12. For another example, the components of the state-change activation circuitry 220 include a magnet and coil that convert or translate mechanical energy into an EMF to initiate the change in state of the electronic device 102, for instance as shown in FIGS. 17, 18, and 19.

For other embodiments, the state-change activation circuitry 220 is configured as an open circuit in the absence of the external force and as a closed circuit to initiate the change in state of the electronic device 102 in response to the external force applied to the connector receptacle 218. Examples of this configuration of state-change activation circuitry 220 are illustrated and described by reference to FIGS. 3, 5, 6, 9, 10, 11, 12, 13, 14, 15, and 16. These illustrated embodiments of the state-change activation circuitry 220 include a set of springs having an internal force, wherein the state-change activation circuitry 220 is configured as the closed circuit when the external force exceeds the internal force of the set of springs. For these embodiments, the state-change activation circuitry 220 further includes at least one of the following to create the closed circuit: a component containing a switching element, a spring-loaded pole, a set of connector pins, a set of connector pads, a set of connector rings, or a piezoelectric sensor. At least some of these components are constructed of conductive material, such as a metal or metal alloy.

For an embodiment, the connector detection circuitry 222 is coupled to the connector receptacle 218 and the controller 212. As such, the connector detection circuitry 222 is configured to detect insertion of the mated connector into the connector receptacle 218 and provide an indication of the insertion to the controller 212 to use to determine whether to maintain the current state of the electronic device 102. The configuration of the connector detection circuitry 222 depends, at least in part, on the particular connector receptacle 218 and mated connector structures. For instance, where the connector receptacle 218 is configured to receive a headset mated connector, e.g., a plug, the connector detection circuitry 222 includes hardware such as contacts and switches to detect when the headset plug has been inserted into the connector receptacle 218.

For a particular embodiment, the connector detection circuitry 222 is embodied on an integrated circuit (IC) as a transistor 222 having its gate connected to a detect pin of the IC such that the gate is biased at a first value, for instance 3 volts (V) as a consequence of the detect pin being connected to the power supply 216, in the absence of a mated connector. The gate of the transistor 222 is biased at a second value, for instance 0V as a consequence of the detect pin being shorted to electrical ground, when the mated connector is inserted into the connector receptacle 218. The different biases of the gate generate different output signals from the transistor 222 that can be provided to the controller 212 to indicate whether or not the mated connector is inserted into the connector receptacle 218. The connector detection circuitry 222 can be implemented to detect three- and/or four-pole mated connectors.

For an embodiment, the falsing detection component 224 represents hardware, and may also include software or firmware, which determines whether a falsing condition exists that prevents a change in state of the electronic device 102. In essence, the falsing detection component 224 infers, based on the detection of the falsing condition, that an external force received on the connector receptacle 218 is likely unintentional. An example falsing condition is where the external force is received on the connector receptacle 218 when the electronic device 102 is in an off power state and a mated connector is detected in the connector receptacle. Another example falsing condition is where the electronic device 102 is detected or sensed to be within a confined space.

For these embodiments, the falsing detection component 224 can receive indications, e.g., sensor output from the sensor hub 206 and signals from the connector detection circuitry 222, to determine the existence of a falsing condition. Accordingly, for a particular embodiment, the functionality of the falsing detection component 224 is integrated with the controller 212. Alternatively, the falsing detection component 224 includes separate hardware that is coupled to the sensor hub 206, the connector detection circuitry 222, and the controller 212 to receive input and, thereby, provide output to the controller 212 indicating detection of a falsing condition.

The state-change initiation-signal detection circuit 226 includes circuitry to detect a state-change initiation signal. For example, the state-change initiation signal is provided as a consequence of a first hardware element of the state-change activation circuitry 220 interacting with a second hardware element of the state-change activation circuitry 220. For one embodiment, the state-change initiation-signal detection circuit 226 operates as a “pass through” to the controller 212 of a substantially unmodified state-change initiation signal. For another embodiment, the state-change initiation-signal detection circuit 226 otherwise indicates to the controller 212 the detection of the state-change initiation signal, such as by providing an expected flag or value.

For a particular embodiment, the state-change initiation-signal detection circuit 226 is embodied on an IC as a transistor 226 having its gate connected to an input pin of the IC such that the gate is biased at a first value, for instance 3V as a consequence of the input pin being connected to the power supply 216, when the state-change activation circuitry 220 is configured as an open circuit in the absence of a sufficient external force onto the connector receptacle 218. The gate of the transistor 226 is biased at a second value, for instance 0V (which represents the state-change activation signal) as a consequence of the input pin being shorted to electrical ground, when the state-change activation circuitry 220 is configured as a closed circuit in response to the external force being applied to the connector receptacle 218.

The different biases of the gate of the transistor 226 cause different output signals from the transistor 226 that can be provided to the controller 212 to indicate the state-change initiation signal generated in response to the external force being applied to the connector receptacle 218. Accordingly, for this embodiment, the state-change activation circuitry 220 is coupled to the power supply 216 and cooperatively configured to provide a first signal value relative to a power supply value in the absence of the external force and a second signal value relative to the power supply value to initiate the change in state of the electronic device 102 in response to the external force applied to the connector receptacle 218. This embodiment of the state-change initiation-signal detection circuit 226 can be implemented, for instance, with the apparatus illustrated in FIGS. 3, 5, 6, 9, 10, 13, 14, 15, and 16.

For another embodiment, the state-change initiation-signal detection circuit 226 is implemented as an analog voltage or current sensor circuit 226. For instance, the sensor circuit 226 senses a first bias voltage or current in the absence of a sufficient external force onto the connector receptacle 218 and provides a resulting first output signal to the controller 212. The sensor circuit 226 senses a second voltage or current (which represents the state-change activation signal) when the state-change activation circuitry 220 is activated in response to the external force being applied to the connector receptacle 218 and provides a resulting second output signal to the controller 112 indicating the state-change initiation signal. This embodiment of the state-change initiation-signal detection circuit 226 can be implemented, for instance, with the apparatus illustrated in FIGS. 11, 12, 17, 18, and 19.

FIG. 3 shows a pictorial diagram illustrating an embodiment of apparatus 300 configured to initiate a change in state of an electronic device using a connector receptacle. For a particular implementation scenario, the apparatus 300 is included in the electronic device 102. The apparatus 300 includes a connector receptacle and state-change activation circuitry coupled to the connector receptacle as further described by reference to FIG. 3.

For this embodiment, the connector receptacle is configured to receive or couple, e.g., connect, to a mated connector of a headset, such as the headset 106. Accordingly, the connector receptacle includes a headset jack 304, which, for example is a 3.5 mm headset jack. The connector receptacle additionally includes a plunger 302 coupled to the top of the headset jack 304. The plunger 302 serves to receive an external force, F_{E}. The external force is translated from the plunger through the headset jack 304 to the state change activation circuitry, which is coupled to the headset jack 304. In some instances, as described later, the external force is of sufficient strength and/or duration to cause the state-change activation circuitry to initiate a change in state of the electronic device 102.

The connector receptacle further includes a chassis 308, surrounding the headset jack 304 and the state-change activation circuitry to, for instance, protect them from debris or damage. In different embodiments, the chassis 308 is constructed of metal or plastic material, or a combination thereof, and is of sufficient tensile strength to accommodate repetitive mating or pairing of the connector receptacle with the mated connector.

The state-change activation circuitry includes a pole 310 and a push button 312. In this case, the pole 310 is a spring-loaded pole having a set of one or more springs (only one spring in this embodiment) with an internal force, F_{I.} That is, for component 310 a spring surrounds a pole. This physical arrangement enables the pole to move vertically within the chassis 308, in response to a force applied and released to and from the spring-loaded pole 310 as a consequence of being coupled to the headset jack 304. The push button 312 includes an element 318, which can be metal for example, and a switching element 320 having a first contact 322 and a second contact 324. For a particular arrangement, the elements 318 and 320 are enclosed in a flexible or bendable material of the push button 312, such a polymer-based material.

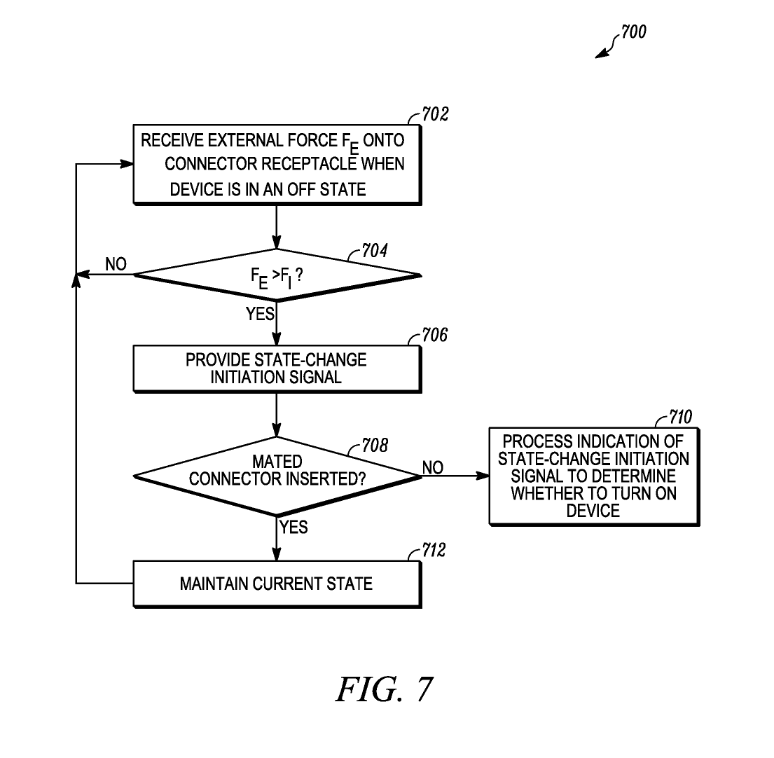

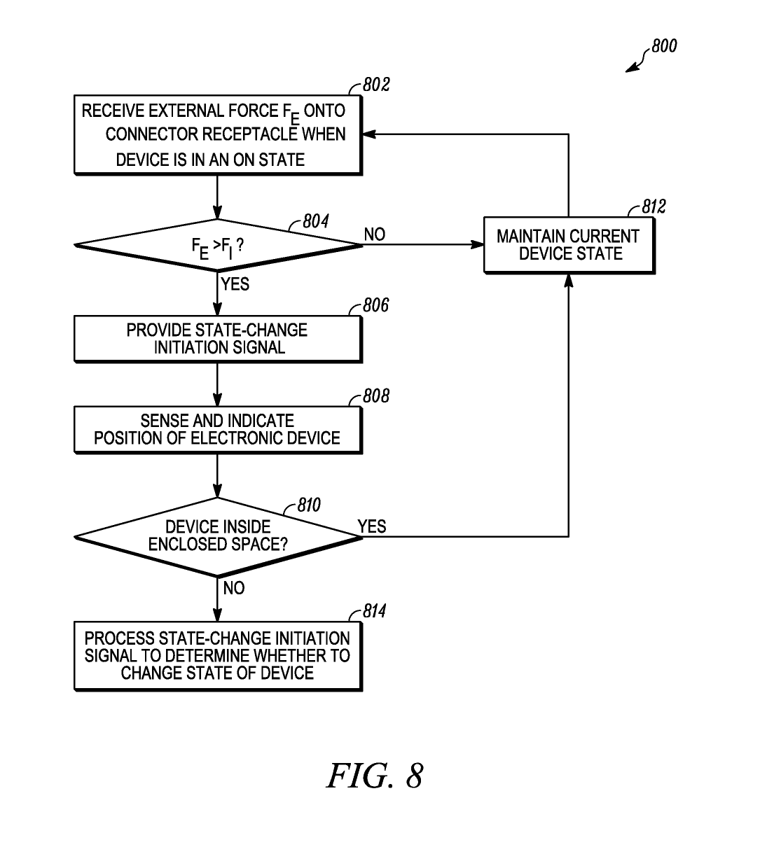

The apparatus 300 also includes the connector detection circuitry 222 coupled to the connector receptacle. The connector detection circuitry 222, in this embodiment, is a headset detection circuit configured to detect insertion of the mated connector 108 of the headset 106. The connector detection circuitry 222 is optional. However, inclusion of the connector detection circuitry 222 can facilitate a better user experience by preventing, through one or more falsing algorithms, the initiation in change in state of the electronic device 102 under circumstances where it is unlikely that the user intended to change the state of the electronic device 102. One such circumstance is when an accessory is connected to the electronic device 102 through the connector receptacle when the electronic device is turned off Details of falsing algorithms are described by reference to FIGS. 7 and 8.

Leads 326 connect to other components of the electronic device 102 to enable generating and/or provision of a state-change initiation signal to initiate a change in state of the electronic device 102. For example, the leads 326 are coupled to one or more components including, but not limited to, the power supply 216, electrical ground or another bias voltage or current, or the state-change initiation-signal detection circuit 226.

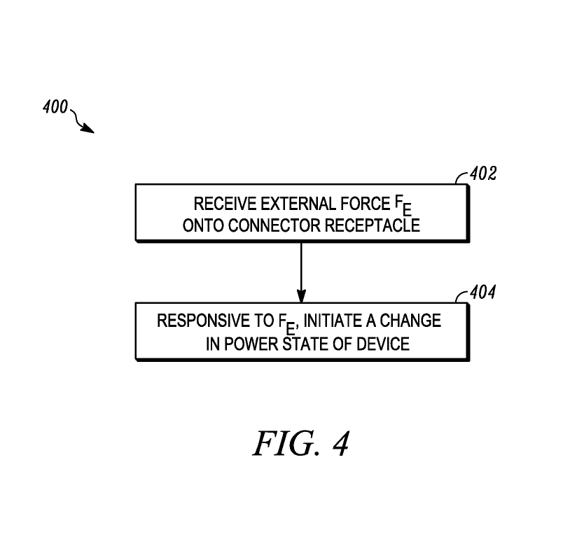

FIG. 4 shows a flow diagram illustrating a method 400 for initiating a change in state of an electronic device using a connector receptacle. For example, an electronic device that includes the apparatus illustrated in any of FIGS. 3, 5, 6 and 9 through 19 is configured for performing the method 400. In accordance with the method 400, the electronic device 102 receives 402 an external force, F_{E}, either directly or indirectly onto the plunger 302 of the connector receptacle of the electronic device 102. For example, a manual press by a user generates an external force directly onto the plunger 302. Whereas, insertion of a mated connector into the connector receptacle can generate an external force indirectly onto the plunger 302.

When the external force is large enough and/or is of sufficient duration, the state-change activation circuitry of the electronic device 102 responds to the external force by initiating 404 a change in state of the electronic device 102. Initiating 404 the change in state can include, for example, generating or causing to be generated a state-change initiation signal. For an embodiment, the external force can be measured in Newtons (N). For a particular embodiment, an external force received onto the plunger 302 of 0.30N to 3.90N is sufficient to cause the initiation of a change in state of the electronic device.

For some embodiments described herein, initiating a change in state includes generating or causing to be generated the state-change initiation signal as a consequence of a first hardware element of the state-change activation circuitry interacting with a second hardware element of the state-change activation circuitry. For example, the state-change initiation signal is provided as a consequence of the first hardware element contacting the second hardware element, as described and illustrated by reference to FIGS. 3, 5, 6, 9, 10, 11, 12, 13, 14, 15, and 16. For other embodiments, the state-change initiation signal is provided as a consequence of the first hardware element inducing an electrical or electromagnetic signal in or from the second hardware element, for example as described and illustrated by reference to FIGS. 11, 12, 17, 18, and 19.

For some embodiments, a falsing algorithm is implemented such that the electronic device 102 (for instance using the controller 212) determines to maintain a current state of the electronic device 102 when the external force is applied to the connector receptacle. For one embodiment, as described by reference to FIG. 7, determining to maintain the current state of the electronic device 102 is based on a detection of the mated connector inserted into the connector receptacle. For another embodiment, as described by reference to FIG. 8, determining to maintain the current state of the electronic device 102 is based on an indication that the electronic device 102 is in an enclosed space.

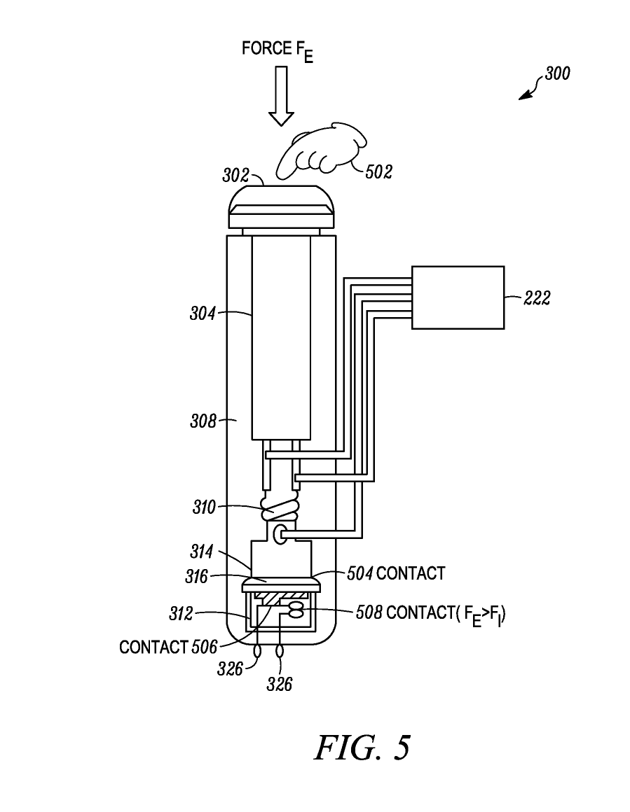

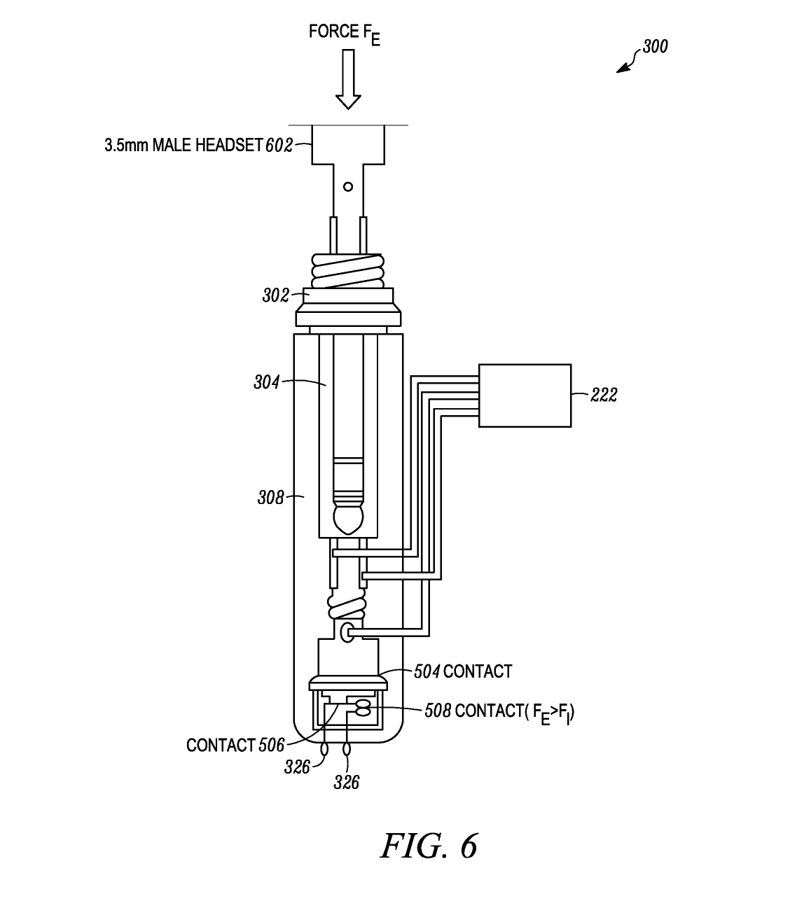

FIGS. 5 and 6 each illustrate the effect of an external force, F_{E}, being applied to the apparatus 300, where the external force exceeds the internal force of the spring-loaded pole 310. Particularly, FIG. 5 illustrates an external force applied by a user 502 to the plunger 302; and FIG. 6 illustrates an external force applied by a 3.5 mm male headset 602 to the plunger 302.

For the apparatus 300, the state-change activation circuitry is configured as an open circuit in the absence of the external force and as a closed circuit to initiate the change in state of the electronic device in response to the external force applied to the connector receptacle. As shown in FIG. 3, the open circuit is illustrated by a separation: between an end 314 of the spring-loaded pole 310 and an end 316 of the push button 312; between the element 318 of the push button 312 and the pad 322 of the switching element 320; and between the pads 322 and 324 of the switching element 320.

Conversely, the state-change activation circuitry is configured as the closed circuit when the external force exceeds the internal force of the set of springs, namely, when F_{E}>F_{I}. The closed circuit is illustrated in FIGS. 5 and 6 by: contact 504 between the end 314 of the spring-loaded pole 310 and the end 316 of the push button 312; contact 506 between the element 318 of the push button 312 and the pad 322 of the switching element 320; and contact 508 between the pads 322 and 324 of the switching element 320. The contacts 504, 506, and 508 cause a state-change initiation signal to be generated at the leads 326.

Thus, apparatus 300 illustrates an embodiment of state-change activation circuitry that includes a switching element and a spring-loaded pole to create the closed circuit. Some of the remaining figures illustrate alternative embodiments of apparatus having state-change activation circuitry 220 that includes: a set of connector pins to generate the closed circuit (e.g., FIGS. 9 and 10); a set of connector pads to generate the closed circuit (e.g., FIGS. 15 and 16); and a set of connector rings to generate the closed circuit (e.g., FIGS. 13 and 14).

FIG. 7 shows a flow diagram illustrating an embodiment of a method 700 for initiating a change in state of an electronic device, e.g., 102, using a connector receptacle, e.g., 218, when the electronic device 102 is in an off state or without normal operating power sufficient to sustain a substantial number of operations for the electronic device 102. For example, an electronic device that includes apparatus illustrated in any of FIGS. 3, 5, 6 and 9 through 16 can be configured to perform the method 700.

Specifically, the electronic device 102 receives 702 an external force F_{E} onto the connector receptacle 218 while the electronic device 102 is initially turned off or has nominal power. When, at block 704, the external force F_{E} exceeds the internal force F_{I} of a set of springs included in the state-change activation circuitry 220, the electronic device 102 through the state-change activation circuitry 220 provides 706 a state-change initiation signal. Otherwise, the method returns to block 702 until the external force F_{E} exceeds the internal force F_{I}.

For one example, the state-change initiation signal is generated when a large enough external force is exerted on the connector receptacle 218 to cause a first hardware element of the state-change activation circuitry 220 to contact a second hardware element of the state-change activation circuitry 220, such as in the embodiments illustrated in FIGS. 3, 5, 6, 9, 10, 13, 14, 15, and 16. For another example, the state-change initiation signal is generated when a large enough external force is exerted on the connector receptacle 218 to cause a first hardware element of the state-change activation circuitry 220 to contact a second hardware element of the state-change activation circuitry 220 with a sufficient amount of pressure, such as in the embodiment illustrated in FIGS. 11 and 12.

Blocks 708 and 712 of the method 700 represent the electronic device 102 implementing a falsing algorithm, whereby the electronic device 102 may remain in the current off state even when a large enough external force is exerted on the connector receptacle 218 to generate the state-change initiation signal. Namely, the connector detection circuitry 222 detects 708 whether a mated connector is inserted into the connector receptacle 218. When the mated connector is detected, the electronic device 102 maintains 712 its current off state, and the method 700 returns to block 702.

Accordingly, the electronic device 102 does not process the state-change initiation signal and, thereby, prevents the electronic device 102 from being turned on when an accessory is plugged into the connector receptacle 218. For one example, outputs of both the state-change initiation-signal detection circuit 226 and the connector detection circuitry 222 are input into “blocking” hardware (such as one or more transistors or switches) on the IC housing the controller 212. When the mated connector is inserted into the connector receptacle 218 and the device 102 is turned off, the signal output from connector detection circuitry 222 prevents the blocking hardware from passing an output signal from the state-change initiation-signal detection circuit 226 that would otherwise power-up the controller 212, or another power management component in the electronic device 102, to determine whether to power-up the electronic device 102 in response to the state-change initiation signal being generated.

Such falsing logic can enhance a user's experience by preventing the electronic device 102 from inadvertently turning on when the user has an accessory connected. For one use-case scenario, a user is listening to audio using a headset plugged into his electronic device 102 while the user is waiting to board an airplane. Upon boarding, the user turns off his device 102 (leaving the headset connected) and puts his device 102 into his pants pocket. While the user is sitting, he would not want the phone 102 to be inadvertently turned back on, for instance during takeoff, due to the mated connector applying a sufficient external force indirectly onto the connector receptacle 218.

When the mated connector is not detected, at 708, the blocking hardware allows the controller 212 or other power management hardware to be awakened to process 710 the output signal from the state-change initiation-signal detection circuit 226, which indicates that a state-change initiation signal was generated. For an embodiment, processing 710 the output signal from the state-change initiation-signal detection circuit 226 allows the controller 212 to determine whether to turn on or facilitate turning on or providing power to other components of the electronic device 102. For one example, the controller 212 uses timers to detect a “long” press on the connector receptacle 218, e.g., of 2 or more seconds, and resultantly turns on the other components of electronic device 102.

FIG. 8 shows a flow diagram illustrating an embodiment of a method 800 for initiating a change in state of an electronic device, e.g., 102, using a connector receptacle, e.g., 218, when the electronic device 102 is powered on or has substantial power to operate. For example, an electronic device that includes apparatus illustrated in any of FIGS. 3, 5, 6 and 9 through 16 can be configured to perform the method 800.

Specifically, the electronic device 102 receives 802 an external force F_{E} onto the connector receptacle 218 while the electronic device 102 is initially turned on. The electronic device may be in a sleep state or an awake state, for instance. When, at block 804, the external force F_{E} exceeds the internal force F_{I} of a set of springs included in the state-change activation circuitry 220, the electronic device 102 through the state-change activation circuitry 220 provides 806 a state-change initiation signal. The state-change initiation signal can be generated, for example, as described by reference to block 706 of FIG. 7. Otherwise, the method returns to block 802 until the external force F_{E} exceeds the internal force F_{I}.

Blocks 808, 810, and 812 of the method 800 represent the electronic device 102 implementing a falsing algorithm, whereby the electronic device 102 may remain in the current state even when a large enough external force is exerted on the connector receptacle 218 to generate the state-change initiation signal. Namely, one or more sensors of the sensor hub 206 are used to sense 808 the environment around the electronic device 102 and provide to the controller 212 signals or data that indicate, for instance, position, location, etc., of the electronic device 102 relative to its environment. Any suitable sensor data can be used including, but not limited to, imager sensor data, proximity sensor data, heat sensor data, etc., to indicate the environment in which the electronic device 102 is located.

The controller 212 uses the signals or data from the sensor hub 206 to determine 810 whether the electronic device 102 is within an enclosed space such as a purse, briefcase, or garment pocket. For example, the controller 212 makes its determination 810 by executing a software algorithm that compares the received sensor data to stored sensor data ranges that indicate whether or not the device 102 is within an enclosed space. When the controller 212 determines 810 that the electronic device 102 is within an enclosed space, the controller 212 ignores the indication that the state-change initiation signal was generated, maintains 812 the current state of the electronic device, and the method 800 returns to block 802.

When the controller 212, at 810, determines that the electronic device 102 is not within an enclosed space, the controller 212 processes 814 the output signal from the state-change initiation-signal detection circuit 226, which indicates that a state-change initiation signal was generated. For an embodiment, processing 814 the output signal from the state-change initiation-signal detection circuit 226 allows the controller 212 to determine using timers whether there was a long press or a “short” press on the connector receptacle while the electronic device 102 is turned on. A short press can be a few hundred milliseconds, for instance. Additionally, while the device 102 is on and not in an enclosed space, the algorithm need not take into consideration whether or not the press occurred with a mated connector inserted. When the controller 212 detects a long press, the controller 212 can initiate the shut down or reset of the electronic device 102, depending upon the length of time of the press. However, when the controller 212 detects a short press, the controller can initiate a change in state of the electronic device 102 (or one or more components thereof) from a sleep state to an awake state or from an awake state to a sleep state.

FIGS. 9 and 10 show pictorial diagrams illustrating apparatus 900, which includes a connector receptacle and state-change activation circuitry physically arranged to initiate a change in state of an electronic device, e.g., 102, in response to an external force applied to the connector receptacle. The connector receptacle includes the plunger 302, the headset jack 304, and the chassis 308, similar in form and function to the identically numbered components shown in as described by reference to FIG. 3. The description of these components is not repeated here for brevity. The state-change activation circuitry includes the spring-loaded pole 310 and a set of connector pins 902 coupled to the chassis 308. The apparatus 900 further includes the headset detection circuitry 222 and the leads 326, which are similar in form and function to the identically numbered components shown in as described by reference to FIG. 3. The description of these components is not repeated here for brevity.

For the apparatus 900, the state-change activation circuitry is configured as an open circuit in the absence of sufficient external force and as a closed circuit to initiate the change in state of the electronic device in response to the external force applied, for instance by a user's hand 402, to the connector receptacle. As shown in FIG. 9, the open circuit is illustrated by a separation between the end 314 of the spring-loaded pole 310 and the connector pins 902. Conversely, the state-change activation circuitry is configured as the closed circuit when the external force exceeds the internal force of the set of springs, namely, when F_{E}>F_{I}. The closed circuit is illustrated in FIG. 10 by contact 1002 between the end 314 of the spring-loaded pole 310 and the connector pins 902. The contact 1002 causes a state-change initiation signal to be generated at the leads 326.

FIGS. 11 and 12 show pictorial diagrams illustrating apparatus 1100, which includes a connector receptacle and state-change activation circuitry physically arranged to initiate a change in state of an electronic device, e.g., 102, in response to an external force applied to the connector receptacle. The connector receptacle includes the plunger 302, the headset jack 304, and the chassis 308, similar in form and function to the identically numbered components shown in as described by reference to FIG. 3. The description of these components is not repeated here for brevity. The state-change activation circuitry includes the spring-loaded pole 310 and a piezoelectric sensor 1102 coupled to the chassis 308. The apparatus 1100 further includes the headset detection circuitry 222 and the leads 326, which are similar in form and function to the identically numbered components shown in as described by reference to FIG. 3. The description of these components is not repeated here for brevity.

For the apparatus 1100, the state-change activation circuitry is configured as an open circuit in the absence of sufficient external force and as a closed circuit to initiate the change in state of the electronic device in response to the external force applied, for instance by a user's hand 402, to the connector receptacle. As shown in FIG. 11, the open circuit is illustrated by a separation between the end 314 of the spring-loaded pole 310 and the piezoelectric sensor 1102. Conversely, the state-change activation circuitry is configured as the closed circuit when the external force exceeds the internal force of the set of springs, namely, when F_{E}>F_{I}. The closed circuit is illustrated in FIG. 12 by contact 1202 between the end 314 of the spring-loaded pole 310 and the piezoelectric sensor 1102.

The contact 1202 causes a mechanical force or pressure to be exerted on the piezoelectric sensor 1102. The piezoelectric sensor 1102 converts the pressure into an electrical charge that appears as a voltage across the leads 326. A voltage sensor circuit coupled between the leads 326 and the state-change initiation-signal detection circuit 226 can detect this voltage. When the voltage exceeds a threshold value, for example, it can trigger the state-change initiation-signal detection circuit 226 to signal the controller 212.

FIGS. 13 and 14 show pictorial diagrams illustrating apparatus 1300, which includes a connector receptacle and state-change activation circuitry physically arranged to initiate a change in state of an electronic device, e.g., 102, in response to an external force applied to the connector receptacle. The connector receptacle includes the plunger 302, the headset jack 304, and the chassis 308, similar in form and function to the identically numbered components shown in as described by reference to FIG. 3. The description of these components is not repeated here for brevity.

The state-change activation circuitry includes the spring-loaded pole 310 and a set of connector rings, which includes an inner connector 1302 and an outer connector ring 1304. The inner connector ring 1302 is coupled to the spring-loaded pole 310, and the outer connector ring 1304 is coupled to the chassis. The circumference of the outer edge of the inner connector ring 1302 and the circumference of at least part of the inner surface of the outer connector ring 1304 are designed such that these surfaces can make physical contact when F_{E}>F_{I}. The apparatus 1300 further includes the headset detection circuitry 222 and the leads 326, which are similar in form and function to the identically numbered components shown in as described by reference to FIG. 3. The description of these components is not repeated here for brevity.

For the apparatus 1300, the state-change activation circuitry is configured as an open circuit in the absence of sufficient external force and as a closed circuit to initiate the change in state of the electronic device in response to the external force applied, for instance by a user's hand 402, to the connector receptacle. As shown in FIG. 13, the open circuit is illustrated by a separation between the inner connector ring 1302 and the outer connector ring 1304. Conversely, the state-change activation circuitry is configured as the closed circuit when the external force exceeds the internal force of the set of springs, namely, when F_{E}>F_{I}. The closed circuit is illustrated in FIG. 14 by contact 1402 between the inner connector ring 1302 and the outer connector ring 1304. The contact 1402 causes a state-change initiation signal to be generated at the leads 326.

FIGS. 15 and 16 show pictorial diagrams illustrating apparatus 1500, which includes a connector receptacle and state-change activation circuitry physically arranged to initiate a change in state of an electronic device, e.g., 102, in response to an external force applied to the connector receptacle. The connector receptacle includes the plunger 302, the headset jack 304, and the chassis 308, similar in form and function to the identically numbered components shown in as described by reference to FIG. 3. The description of these components is not repeated here for brevity.

The state-change activation circuitry includes: a set of springs 1502 and 1504 having an internal force F_{I}; a set of connector pads 1506 and 1508, which can be the same or different dimensions; and a set of wires 1510 and 1512. A first portion of the wires 1510 and 1512 is coupled to the outer surface of the headset jack 304, such that the wires 1510 and 1512 move with the headset jack 304. The spring 1502 couples a distal end of the wire 1510 to the bottom of the chassis 308. The spring 1504 couples a distal end of the wire 1512 to the bottom of the chassis 308. The connection between the headset jack 304, the wires 1510, 1512, the springs 1502, 1504, and the chassis 308 allows the springs 1502, 1504 to compress when an external force is applied to the plunger 302 and to decompress as the external force is released. The connector pad 1508 is coupled to the bottom of the chassis 308, and the connector pad 1506 is coupled to the wire/spring combination 1512/1514, such that a space is created between the connector pads 1506 and 1508 when F_{E}<F_{I}. The apparatus 1500 further includes the headset detection circuitry 222 and the leads 326, which are similar in form and function to the identically numbered components shown in as described by reference to FIG. 3. The description of these components is not repeated here for brevity.

For the apparatus 1500, the state-change activation circuitry is configured as an open circuit in the absence of sufficient external force and as a closed circuit to initiate the change in state of the electronic device in response to the external force applied, for instance by a user's hand 402, to the connector receptacle. As shown in FIG. 15, the open circuit is illustrated by a separation between the connector pad 1506 and the connector pad 1508. Conversely, the state-change activation circuitry is configured as the closed circuit when the external force exceeds the internal force of the set of springs, namely, when F_{E}>F_{I}. The closed circuit is illustrated in FIG. 16 by contact 1602 between the connector pad 1506 and the connector pad 1508. The contact 1602 causes a state-change initiation signal to be generated at the leads 326.

FIGS. 17, 18, and 19 show pictorial diagrams illustrating apparatus 1700, which includes a connector receptacle and state-change activation circuitry physically arranged to initiate a change in state of an electronic device, e.g., 102, in response to an external force applied to the connector receptacle. The connector receptacle includes the plunger 302, the headset jack 304, and the chassis 308, similar in form and function to the identically numbered components shown in as described by reference to FIG. 3. The description of these components is not repeated here for brevity.

The state-change activation circuitry includes a spring-loaded pole 1710 having a set of springs 1702 with an internal force F_{I}, a magnet 1704, and a coil 1706. The springs 1702 are connected orthogonally between the pole 1710 and the chassis 308 (as opposed to a single spring surrounding the pole). Otherwise, the spring-loaded pole 1710 is similar in form and function to spring-loaded pole 310 shown in as described by reference to FIG. 3. The description of the spring-loaded pole 310 is not repeated here for brevity. The coil 1706 is coupled to the bottom of the chassis 308, and the magnet 1704 is coupled to a distal end 1714 of the pole 1710, such that the magnet moves with the pole 1710. The apparatus 1700 further includes the headset detection circuitry 222 and the leads 326, which are similar in form and function to the identically numbered components shown in as described by reference to FIG. 3. The description of these components is not repeated here for brevity.

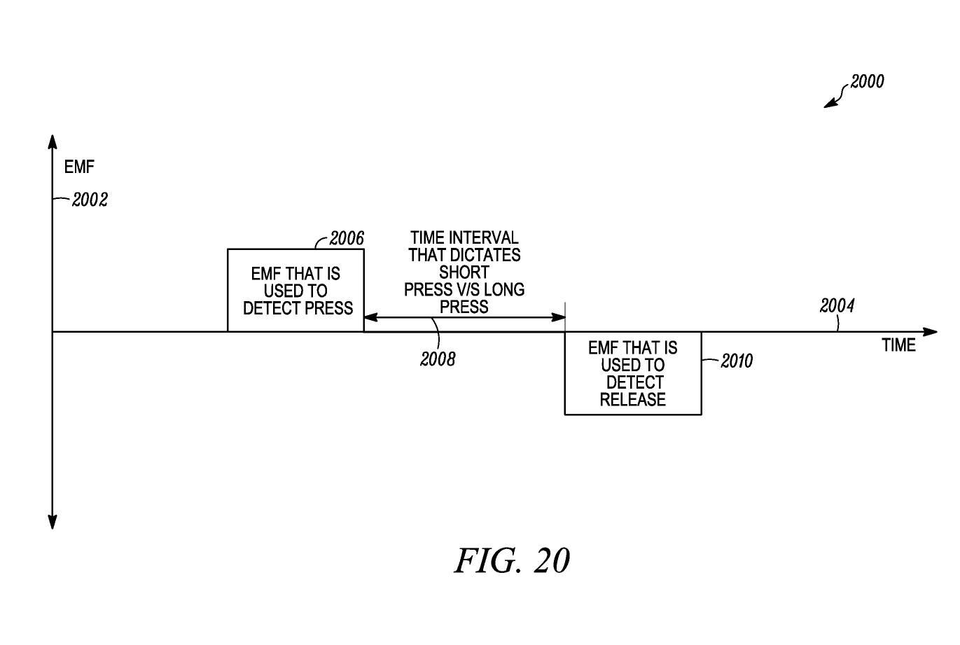

The state-change activation circuitry applies Faraday's Law to induce a voltage or electromagnetic force (EMF) in the coil 1706 as a result of relative motion between the magnet 1704 and the coil 1706. The EMF can be detected, for instance as a voltage, at the leads 326 by a voltage sensor circuit. The operation of the state-change activation circuitry is described in detail by reference FIGS. 17, 18, 19, and 20. FIG. 17 illustrates the state-change activation circuitry, wherein the magnet 1704 is at rest in a first position relative to the coil 1706 when no external force is applied to the plunger 302. Since there is no relative movement between the magnet 1704 and the coil 1706, there is no change in magnetic flux through the coil 1706, and, thus, no EMF is induced in the coil 1706. Turning momentarily to FIG. 20, a diagram 2000 is illustrated which shows induced EMF on an x-axis 2002 versus time on a y-axis 2004. The timeline axis 2004 intersects the EMF axis 2002 at a bias EMF value corresponding to the magnet 1704 being at rest relative to the coil 1706.

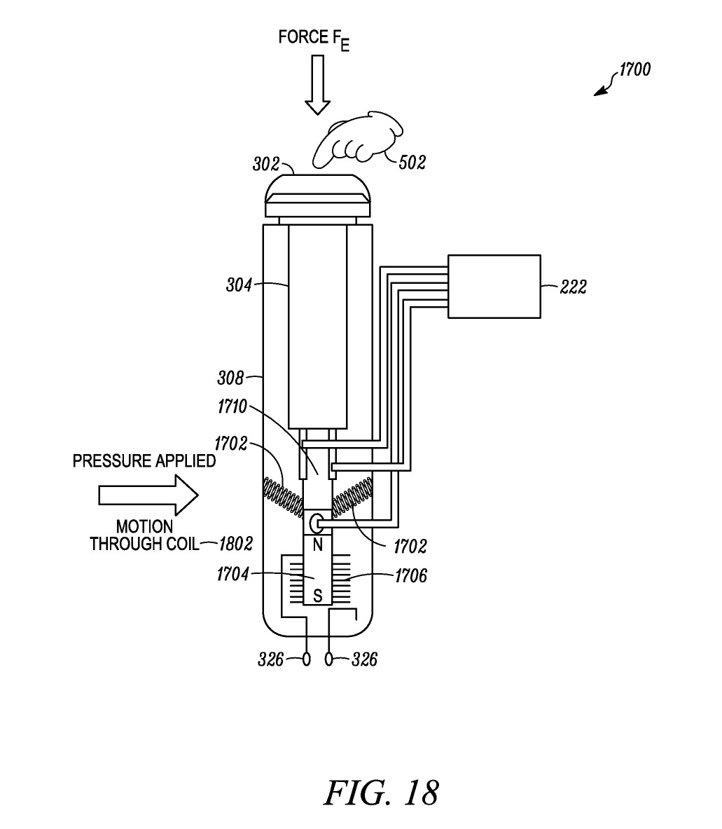

FIG. 18 illustrates the state-change activation circuitry, wherein the magnet 1704 is at rest in a second position relative to the coil 1706 in response to an external force applied, in this case by the hand 402, to the plunger 302. As shown, when in the second position, the magnet 1704 is within or at least partially surrounded by the coil 1706. However, since there is no relative movement between the magnet 1704 and the coil 1706 when the magnet 1704 is in the second position, there is no change in magnetic flux through the coil 1706, and, thus, no EMF is induced in the coil 1706. This is illustrated in FIG. 20 by a time interval 2008 during which the EMF is at the bias EMF value.

As the magnet 1704 transitions from the first position to the second position and, thereby, moves 1802 relative to the coil 1706, the magnetic flux through the coil 1706 changes, which induces an EMF in the coil. The value of the induced EMF is illustrated in FIG. 20 by a block 2006. The value of the induced EMF is proportional to the product of the number of loops of the coil 1706 and the rate of movement of the magnet 1704 through the coil 1706. The state-change activation circuitry can be designed such that internal force of the springs 1702 facilitates a rate of movement that is fast enough to produce an EMF value that is detectable.

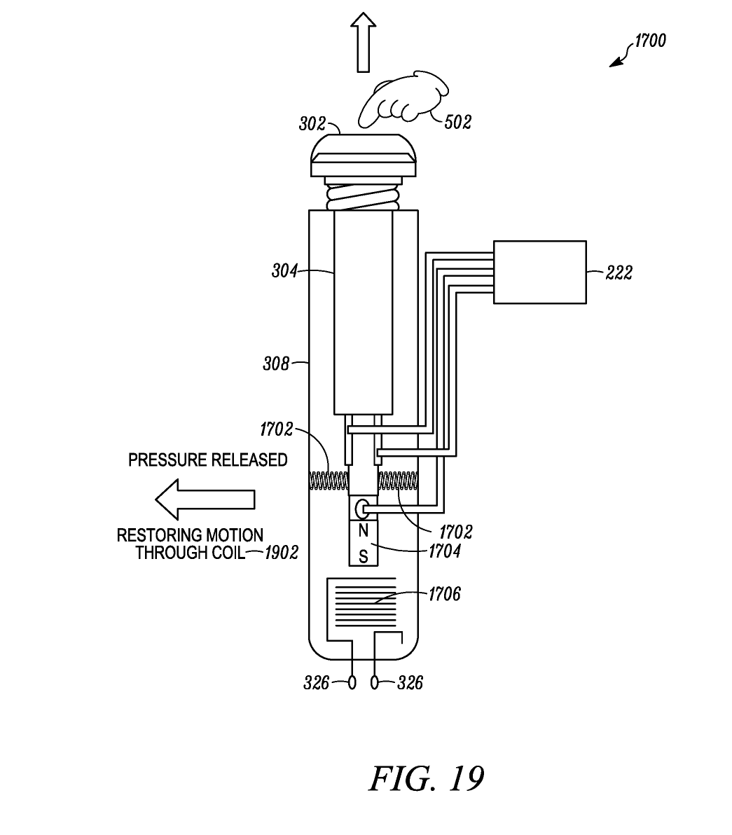

FIG. 19 illustrates the state-change activation circuitry, wherein the magnet 1704 is at rest in the first position relative to the coil 1706 in response to the external force having been released from the plunger 302. As the magnet 1704 transitions from the second position back to the first position and, thereby, moves 1902 relative to the coil 1706, the magnetic flux through the coil 1706 changes, which induces an EMF in the coil. The value of the induced EMF is illustrated in FIG. 20 by a block 2010. Since the motion 1902 of the magnet 1704 through the coil 1706 is in the opposite direction of the motion 1802, the induced EMF value illustrated at 2010 is opposite in polarity from the induced EMF value illustrated at 2006.

The controller 2012 can use timers to measure the time interval 2108 to detect a long press or a short press onto the plunger and proceed to cause the corresponding change in state of the electronic device 102. Additionally, similar falsing algorithms as described by reference to FIGS. 7 and 8 can be implemented with the embodiment of apparatus 1700.

Moreover, as before, since there is no relative movement between the magnet 1704 and the coil 1706 when the magnet 1704 is in the first position, there is no change in magnetic flux through the coil 1706, and, thus, no EMF is induced in the coil 1706. This is illustrated in FIG. 20 by a time interval after the block 2010 during which the EMF is back at the bias EMF value.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover, in this document, relational terms such as first and second, top and bottom, and the like are used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements; but also includes other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments are comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. An apparatus comprising:
a connector receptacle physically arranged to receive a mated connector of an external device to an electronic device;
state-change activation circuitry coupled to the connector receptacle, wherein the state-change activation circuitry is physically arranged to initiate a change in state of the electronic device in response to an external force applied to the connector receptacle.

2. The apparatus of claim 1, wherein the state-change activation circuitry is physically arranged to convert mechanical energy to an electrical signal to initiate the change in state of the electronic device.

3. The apparatus of claim 2, wherein the state-change activation circuitry comprises one of:
a piezoelectric sensor; or
a magnet and coil.

4. The apparatus of claim 1, wherein the state-change activation circuitry is coupled to a power supply and cooperatively configured to provide a first signal value relative to a power supply value in the absence of the external force and a second signal value relative to the power supply value to initiate the change in state of the electronic device in response to the external force applied to the connector receptacle.

5. The apparatus of claim 1, wherein the state-change activation circuitry is physically arranged as an open circuit in the absence of the external force and as a closed circuit to initiate the change in state of the electronic device in response to the external force applied to the connector receptacle.

6. The apparatus of claim 5, wherein the state-change activation circuitry includes a set of springs having an internal force, wherein the state-change activation circuitry is physically arranged as the closed circuit when the external force exceeds the internal force of the set of springs.

7. The apparatus of claim 5, wherein the state-change activation circuitry further comprises as least one of the following to create the closed circuit:
a component containing a switching element;
a spring-loaded pole;
a set of connector pins;
a set of connector pads;
a set of connector rings; or
a piezoelectric sensor.

8. An electronic device comprising:
a connector receptacle physically arranged to receive a mated connector of an external device to the electronic device;
state-change activation circuitry coupled to the connector receptacle, wherein the state-change activation circuitry comprises first and second hardware elements physically arranged to cooperatively operate in response to an external force applied to the connector receptacle to, thereby, initiate a change in state of the electronic device.

9. The electronic device of claim 8, wherein the first and second hardware elements comprise at least two of:
a spring-loaded pole;
a component containing a switching element;
a connector pin;
a connector ring;
a connector pad;
a spring;
a wire;
a magnet;
a coil; or
a piezoelectric sensor.

10. The electronic device of claim 8, wherein the connector receptacle is physically arranged to receive the mated connector of an accessory device, a charging device, or an auxiliary device.

11. The electronic device of claim 8 further comprising a controller coupled to the state-change activation circuitry, wherein the controller is configured to determine whether to maintain a current state of the electronic device when the external force is applied to the connector receptacle.

12. The electronic device of claim 11 further comprising connector detection circuitry coupled to the connector receptacle and the controller, wherein the connector detection circuitry is configured to detect insertion of the mated connector into the connector receptacle and provide an indication of the insertion to the controller to use to determine whether to maintain the current state of the electronic device.

13. The electronic device of claim 12 further comprising a sensor hub coupled to the controller, wherein the sensor hub is configured to sense positioning of the electronic device and provide an indication of the positioning of the electronic device to the controller to use to determine whether to maintain the current state of the electronic device.

14. A method comprising:
receiving an external force onto a connector receptacle of an electronic device, wherein the connector receptacle is physically arranged to receive a mated connector of an external device to the electronic device;
responsive to the external force, initiating a change in state of the electronic device.

15. The method of claim 14, wherein initiating a change in state comprises sending a state-change initiation signal as a consequence of a first hardware element of a state-change activation circuitry interacting with a second hardware element of the state-change activation circuitry.

16. The method of claim 15, wherein the state-change initiation signal is sent as a consequence of the first hardware element contacting the second hardware element.

17. The method of claim 15 wherein the state-change initiation signal is sent as a consequence of the first hardware element inducing an electrical signal in or from the second hardware element.

18. The method of claim 14 further comprising determining to maintain a current state of the electronic device when the external force is applied to the connector receptacle.

19. The method of claim 18, wherein determining to maintain the current state of the electronic device is based on a detection of the mated connector inserted into the connector receptacle.

20. The method of claim 18, wherein determining to maintain the current state of the electronic device is based on an indication that the electronic device is in an enclosed space.
